(19) United States
(12) Patent Application Publication
(10) Pub. No.: US 2025/0380605 A1
(43) Pub. Date: Dec. 11, 2025

(54) APPARATUS FOR MANUFACTURING DISPLAY APPARATUS AND METHOD OF MANUFACTURING DISPLAY APPARATUS

(71) Applicant: Samsung Display Co., Ltd., Yongin-Si (KR)

(72) Inventors: Junhyeuk Ko, Yongin-si (KR); Mingoo Kang, Yongin-si (KR); Yalim Kim, Yongin-si (KR); Dongha Kim, Yongin-si (KR); Seungchan Kim, Yongin-si (KR); Sukha Ryu, Yongin-si (KR); Ilseob Yoon, Yongin-si (KR)

(21) Appl. No.: 19/197,198

(22) Filed: May 2, 2025

(30) Foreign Application Priority Data
Jun. 11, 2024 (KR) 10-2024-0075675

(51) Int. Cl. H10K 71/16; C23C 14/04; H01L 21/687; H10K 59/12

(52) U.S. Cl. CPC H10K 71/166; C23C 14/042; H01L 21/68785; H10K 59/1201

(57) ABSTRACT

An apparatus for manufacturing a display apparatus includes a chamber, a mask assembly disposed inside the chamber to face a display substrate, a holder part disposed inside the chamber, the holder part including a cooling passage through which a cooling material flows, and a deposition source disposed inside the chamber and configured to supply a deposition material such that the deposition material passes through the mask assembly and is deposited on the display substrate. At least one of the holder part and the mask assembly is movable between a first position at which the holder part supports the display substrate and a second position at which the holder part is in contact with the mask assembly.

### CROSS-REFERENCE TO RELATED APPLICATION

This application is based on and claims priority under 35 U.S.C. § 119 to Korean Patent Application No. 10-2024-0075675, filed on Jun. 11, 2024, in the Korean Intellectual Property Office, the disclosure of which is incorporated by reference herein in its entirety.

### BACKGROUND

### Field

One or more embodiments relate to an apparatus and a method, and more particularly, to an apparatus for manufacturing a display apparatus and a method of manufacturing a display apparatus.

### Description of the Related Art

Mobile electronic devices such as tablet personal computers (PCs) and mobile phones are widely used today. Such an electronic device commonly includes a display apparatus to support various functions, for example, to provide a user with visual information, such as images. Recently, as the components used to drive a display apparatus have been miniaturized, the proportion of an electronic device occupied by a display apparatus has gradually increased, and structures that permit bending or folding of a display apparatus are being developed to provide a compact configuration of the display apparatus.

### SUMMARY

One or more embodiments disclosed herein include efficiently cooling a mask assembly in a deposition process. However, such a technical objective is just an example, and the disclosure is not limited thereto. Additional aspects will be set forth in part in the description which follows and, in part, will be apparent from the description, or may be learned by practice of the presented embodiments of the disclosure.

According to one or more embodiments, an apparatus for manufacturing a display apparatus includes a chamber, a mask assembly disposed inside the chamber to face a display substrate, a holder part that is inside the chamber, the holder part including a cooling passage through which a cooling material flows, and a deposition source disposed inside the chamber and configured to supply a deposition material such that the deposition material passes through the mask assembly and is deposited on the display substrate. At least one of the holder part and the mask assembly may be movable between a first position at which the holder part supports the display substrate and a second position at which the holder part is in contact with the mask assembly.

The holder part may include a holder frame including a holder opening, and a contact portion extending from the holder frame toward the holder opening to be in contact with the display substrate.

The cooling passage may include a first passage disposed inside the holder frame to surround the holder opening. The cooling passage may further include a second passage extending from the first passage and having at least a portion disposed inside the contact portion.

The apparatus may further include a supply part configured to supply the cooling material to the holder part. The cooling passage may further include a third passage disposed inside the holder frame to supply the cooling material from the supply part to the first passage. The cooling passage may further include a fourth passage disposed inside the holder frame such that the cooling material returns from the first passage to the supply part.

The mask assembly may include a first mask portion, a second mask portion extending in a first direction from the first mask portion to the display substrate, and a mask opening passing through the first mask portion and the second mask portion in the first direction. A width of the second mask portion may be less than a width of the first mask portion. The holder part may be in contact with the first mask portion at the second position. The holder part may be apart from the first mask portion at the second position. A thickness of the second mask portion may be greater than a thickness of the holder part.

According to one or more embodiments, a method of manufacturing a display apparatus includes flowing a cooling material through a cooling passage disposed inside a holder part, bringing a display substrate into a chamber, moving the holder part between a first position that supports the display substrate and a second position in contact with a mask assembly, and a deposition source supplying a deposition material.

The holder part may include a holder frame including a holder opening, and a contact portion extending from the holder frame toward the holder opening to be in contact with the display substrate.

The flowing of the cooling material through the cooling passage may include flowing the cooling material through a first passage disposed inside the holder frame such that the cooling material surrounds the holder opening.

The flowing of the cooling material through the cooling passage may further include flowing the cooling material through a second passage extending from the first passage and having at least a portion disposed inside the contact portion.

The method may further include a supply part supplying the cooling material to the holder part. The flowing of the cooling material through the cooling passage may further include flowing the cooling material through a third passage disposed inside the holder frame such that the cooling material is supplied from the supply part to the first passage. The flowing of the cooling material through the cooling passage may further include flowing the cooling material through a fourth passage disposed inside the holder frame such that the cooling material returns from the first passage to the supply part.

The mask assembly may include a first mask portion, a second mask portion extending in a first direction from the first mask portion to the display substrate, and a mask opening passing through the first mask portion and the second mask portion in the first direction. A width of the second mask portion may be less than a width of the first mask portion. The holder part may be in contact with the first mask portion at the second position. The holder part may be apart from the first mask portion at the second position.

A thickness of the second mask portion may be greater than a thickness of the holder part.

These and/or other aspects will become apparent and more readily appreciated from the following detailed description, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a cross-sectional view of an apparatus for manufacturing a display apparatus according to an embodiment.

FIG. 2 is a schematic plan view of a holder part according to an embodiment.

FIG. 3 is a schematic cross-sectional view of a holder part according to an embodiment.

FIG. 4 is a schematic plan view of a mask assembly according to an embodiment.

FIG. 5 is a schematic cross-sectional view of a mask assembly according to an embodiment.

FIGS. 6, 7, 8, 9, and 10 are schematic cross-sectional views of an apparatus during manufacturing of a display apparatus according to an embodiment.

FIG. 11 is a schematic plan view of a display apparatus according to an embodiment.

FIG. 12 is a schematic cross-sectional view of a display apparatus according to an embodiment.

### DETAILED DESCRIPTION

Some embodiments, examples of which are illustrated in the accompanying drawings, are described below. In this regard, the disclosed embodiments may have different forms and should not be construed as being limited to the specific examples set forth herein. Accordingly, the example embodiments described below and illustrated in the figures, are presented as examples to explain aspects of the present description.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

Sizes of elements in the drawings may be exaggerated or reduced for convenience of explanation or illustration. As an example, the size and thickness of each element shown in the drawings may be arbitrarily represented for convenience, and thus, the disclosure is not necessarily limited thereto.

The x-axis, the y-axis and the z-axis are not limited to being three axes of a rectangular coordinate system and may be interpreted in a broader sense. For example, the x-axis, the y-axis, and the z-axis may be perpendicular to one another or may define different directions that are not perpendicular to one another.

Disclosed processes may generally be performed in an order different from the described order. As an example, two processes successively described may be simultaneously performed substantially in parallel or may be performed in the opposite order.

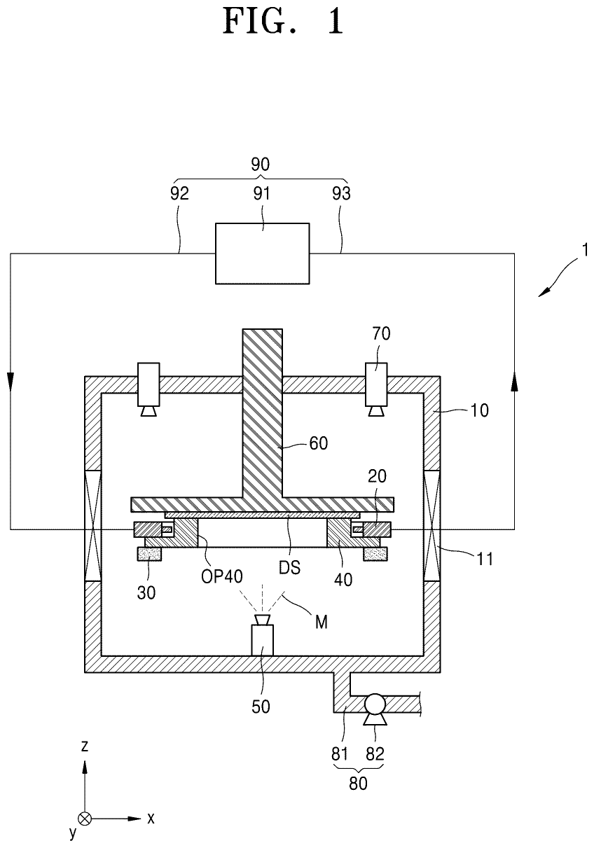

FIG. 1 is a cross-sectional view of an apparatus 1 for manufacturing a display apparatus according to an embodiment. The apparatus 1 may include a chamber 10, a holder part 20, a supporter 30, a mask assembly 40, a deposition source 50, a magnetic force part 60, a vision part 70, a pressure adjustor 80, and a supply part 90.

The chamber 10 may contain a space. A display substrate DS and the mask assembly 40 may in the space inside the chamber 10. In this case, a portion of the chamber 10 may be open. A gate valve 11 may be installed in the open portion of the chamber 10. In this case, the open portion of the chamber 10 may be opened or closed according to an operation of the gate valve 11.

The display substrate DS may include at least one of an organic layer, an inorganic layer, and a metal layer on a substrate 100, which is described below, and the display substrate DS may be undergoing processing to manufacture a display apparatus. Alternatively, the display substrate DS may include the substrate 100 on which any of the organic layer, the inorganic layer, and the metal layer has not yet been deposited.

The holder part 20 is disposed inside the chamber 10 and may support the display substrate DS. The holder part 20 is on the mask assembly 40. The holder part 20 may have a plate shape and may be fixed inside the chamber 10. In another embodiment, the holder part 20 may have a shuttle form on which the display substrate DS sits and which is linearly movable inside the chamber 10. In another embodiment, the holder part 20 may include an electrostatic chuck or an adhesive chuck disposed in the chamber 10, and the chuck may be fixed or movable inside the chamber 10.

The supporter 30 may support the mask assembly 40. In this case, the supporter 30 may be inside the chamber 10. The supporter 30 may permit fine-adjustment of the position of the mask assembly 40. In this case, the supporter 30 may include a driver, an alignment unit, or the like that may separately move the mask assembly 40 in different directions.

In another embodiment, the supporter 30 may have a shuttle form. In this case, the mask assembly 40 may sit on the supporter 30. The supporter 30 may be configured to transfer the mask assembly 40. As an example, the supporter 30 may move outside of the chamber 10 where the mask assembly 40 is placed to sit on the supporter 30, and then the supporter 30 may enter the chamber 10 from the outside of the chamber 10 and thereby move the mask assembly 40 into the chamber 10.

The mask assembly 40 may be disposed to face the display substrate DS inside the chamber 10. A deposition material M may pass through a mask opening OP40 of the mask assembly 40 and be deposited on the display substrate DS.

The deposition source 50 may face the mask assembly 40 and may supply the deposition material M in a form or state such that the deposition material M may pass through the mask assembly 40 and be deposited on the display substrate DS. In one example, the deposition source 50 may evaporate or sublimate the deposition material M by applying heat to the deposition material M. The deposition source 50 may be fixed inside the chamber 10, or the deposition source 50 may be linearly movable in at least one direction inside the chamber 10.

The magnetic force part 60 may be disposed inside the chamber 10 to face the display substrate DS and/or the mask assembly 40. In this case, the magnetic force part 60 may apply magnetic force to the mask assembly 40 and press the mask assembly 40 toward or onto a surface of the display substrate DS.

The vision part 70 may be disposed in the chamber 10 to observe or capture the positions of the display substrate DS and the mask assembly 40. In this case, the vision part 70 may include a camera configured to capture images of the display substrate DS and the mask assembly 40. The positions or orientations of the display substrate DS and the mask assembly 40 may be determined based on the images captured by the vision part 70, and transformation or deformation of the mask assembly 40 may be identified. In addition, the holder part 20 may be configured to fine-adjust the position of the display substrate DS, or the supporter 30 may be configured to fine-adjust the position of the mask assembly 40 based on the captured images. The following primarily describes details for the case where the supporter 30 is configured to fine-adjust the position of the mask assembly 40 and align the positions of the display substrate DS and the mask assembly 40.

The pressure adjustor 80 may be connected to the chamber 10 and configured to adjust the inner pressure of the chamber 10. As an example, the pressure adjustor 80 may adjust or maintain the inner pressure of the chamber 10 to be equal or similar to the atmospheric pressure. As another example, the pressure adjustor 80 may adjust or maintain the inner pressure of the chamber 10 to be equal or similar to a vacuum state.

The pressure adjustor 80 may include a connection pipe 81 and a pump 82. The connection pipe 81 may be connected to the chamber 10, and the pump 82 may be installed on the connection pipe 81. In this case, the pump 82 may operate to introduce external air through the connection pipe 81 into the chamber 10 or to guide gas inside the chamber 10 through the connection pipe 81 to the outside of the chamber 10.

The supply part 90 may supply a cooling material to the holder part 20. The supply part 90 may include a storage 91, a supply passage 92, and a return passage 93. As an example, the cooling material may be coolant including cooling water and the like.

The storage 91 may store the cooling material. The cooling material may be received and stored inside the storage 91. Although FIG. 1 shows an embodiment in which the storage 91 is outside the chamber 10, this is just an example and the storage 91 may be inside the chamber 10. Hereinafter, for convenience of description, the following primarily describes the case where the storage 91 is outside the chamber 10.

The supply passage 92 may connect the storage 91 to the holder part 20. One side of the supply passage 92 may be connected to the storage 91 outside the chamber 10, and the other side of the supply passage 92 may be connected to the holder part 20 inside the chamber 10. That is, the supply passage 92 may pass through the chamber 10. The supply passage 92 may provide a flow path through which the cooling material stored in the storage 91 is supplied to the holder part 20.

The return passage 93 may connect the storage 91 to the holder part 20. One side of the return passage 93 may be connected to the storage 91 outside the chamber 10, and the other side of the return passage 93 may be connected to the holder part 20 inside of the chamber 10. That is, the return passage 93 may pass through the chamber 10. The return passage 93 may provide a flow path through which the cooling material flowing in the holder part 20 returns to the storage 91.

The cooling material may circulate while sequentially flowing through the storage 91, the supply passage 92, the holder part 20, and the return passage 93. As an example, the storage 91 may have a separate pump to circulate the cooling material.

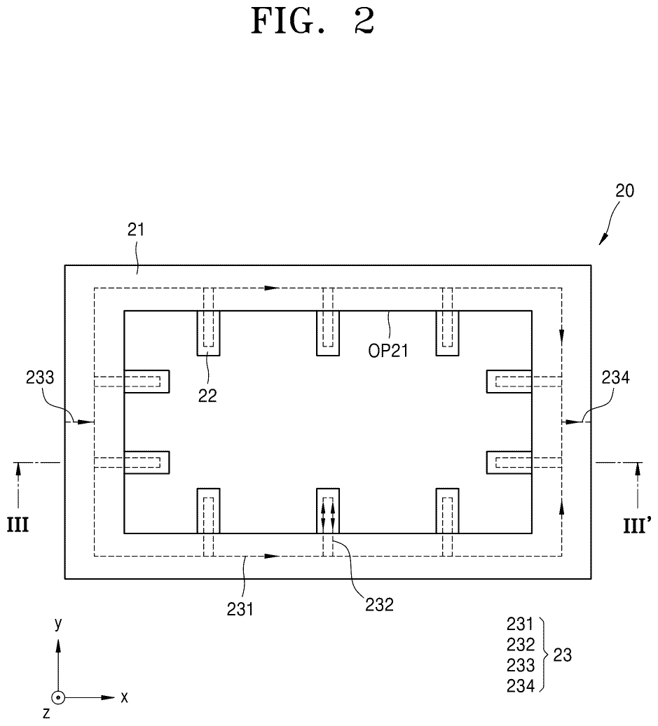

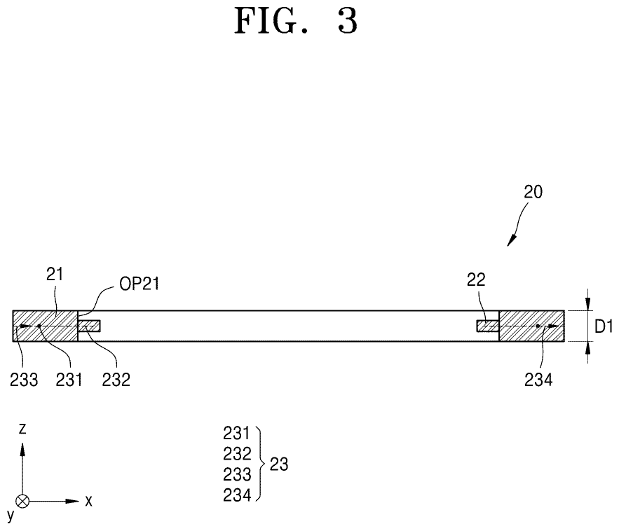

FIG. 2 is a schematic plan view of the holder part 20 according to an embodiment, and FIG. 3 is a schematic cross-sectional view of the holder part 20 according to an embodiment. Specifically, FIG. 3 is a cross-sectional view of the holder part 20, taken along line III-III′ of FIG. 2.

Referring to FIGS. 2 and 3, the holder part 20 may include a holder frame 21, a contact portion 22, and a cooling passage 23.

The holder frame 21 may be formed by connecting a plurality of sides and may include a holder opening OP21 defined by the plurality of sides. That is, the holder opening OP21 may be formed by being surrounded by the plurality of side structures and formed to pass through the center of the holder frame 21 in a first direction (e.g., a +z axis and/or −z axis direction).

In an embodiment, the holder frame 21 may be a quadrangular frame. However, the shape of the holder frame 21 is not limited thereto and may be various polygonal shapes. Hereinafter, for convenience of description, the following primarily describes the case where the holder frame 21 is a quadrangular frame.

In the case where the holder frame 21 is a quadrangular frame, the plurality of side structures may include a first side structure extending in a second direction (e.g., a +x axis and/or −x axis direction) and a second side structure extending in a third direction (e.g., a +y axis and/or −y axis direction). In this case, the first direction (e.g., the +z axis and/or −z axis direction), the second direction (e.g., the +x axis and/or −x axis direction) and the third direction (e.g., the +y axis and/or −y axis direction) may be at an angle with, e.g., perpendicular to, each other. The first side structure may include a pair of linear side pieces that are parallel to and face each other, and the second side structure may include a pair of linear side pieces that are parallel to and face each other. The first side structure may be connected to the second side structure. In an embodiment, the first side structure may extend along a long side of the holder frame 21, and the second side structure may extend along a short side of the holder frame 21. However, embodiments in accordance with this disclosure are not limited thereto, and the first side structure may extend along a short side of the holder frame 21, and the second side structure may extend along a long side of the holder frame 21, or the lengths of the first side structure and the second side structure may be the same. Hereinafter, for convenience of description, the following primarily describes the case where the first side structure is longer than the second side structure.

The contact portion 22 may extend from the holder frame 21 into the holder opening OP21. The contact portion 22 may be integrally formed with the holder frame 21. The contact portion 22 may include a plurality of separated contact portions 22, and the plurality of contact portions 22 may be arranged along the perimeter of the holder opening OP21. As an example, the plurality of contact portions 22 may be spaced apart at equal intervals along the perimeter of the holder opening OP21. Each contact portion 22 may protrude from the holder frame 21 in a lengthwise direction. As an example, each contact portion 22 may have a cylindrical or hexahedral shape with a lengthwise direction into the holder opening OP21. However, this is an example, and the shape of the contact portion 22 is not limited thereto.

The cooling passage 23 may be disposed inside at least one of the holder frame 21 and the contact portion 22, and the cooling material may flow therethrough. The cooling passage 23 may be a vacant passage through which the cooling material may flow. The cooling passage 23 may include a first passage 231, a second passage 232, a third passage 233, and a fourth passage 234.

The first passage 231 may be disposed inside the holder frame 21 to surround the holder opening OP21. The first passage 231 may be provided in a closed cycle or closed loop shape. Although FIG. 2 shows an example in which the first passage 231 has a quadrangular shape, this is just one example and the shape of the first passage 231 is not limited thereto. As an example, the first passage 231 may have a closed curve shape or have a serpentine shape.

The second passage 232 may extend from the first passage 231 and have at least a portion disposed inside the contact portion 22. The number of separated second passages 232 may correspond to the number of separated contact portions 22. That is, in the case including a plurality of separate contact portions 22, the second passage 232 may include a plurality of separated second contact passages 232. The second passage 232 and the first passage 231 may be interconnected to form a closed cycle or closed loop shape. Although FIG. 2 shows an example in which each second passage 232 has a quadrangular shape, this is just one example and the shape of the second passage 232 is not limited thereto. As an example, each second passage 232 may have a closed curve shape or a serpentine shape.

The third passage 233 may be disposed inside the holder frame 21 such that the cooling material is supplied from the supply part 90 (see FIG. 1) to the first passage 231. The third passage 233 may be connected to the first passage 231 and may allow the first passage 231 to communicate with the outside of the holder frame 21.

The fourth passage 234 may be disposed inside the holder frame 21 such that the cooling material returns from the first passage 231 to the supply part 90 (see FIG. 1). The fourth passage 234 may be connected to the first passage 231 and may allow the first passage 231 to communicate with the outside of the holder frame 21.

In the illustrated embodiment, the cooling material may be introduced into the holder frame 21 through the third passage 233, may then flow through the holder frame 21 through the first passage 231, and then may be discharged to the outside of the holder frame 21 through the fourth passage 234. The cooling material may also flow through the inside of the contact portion 22 through the second passage 232, which is connected to the first passage 231.

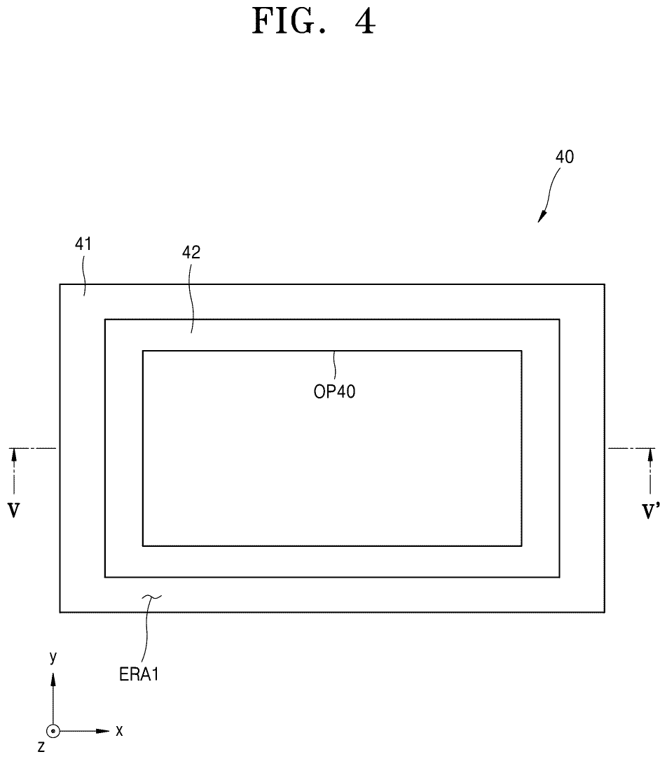

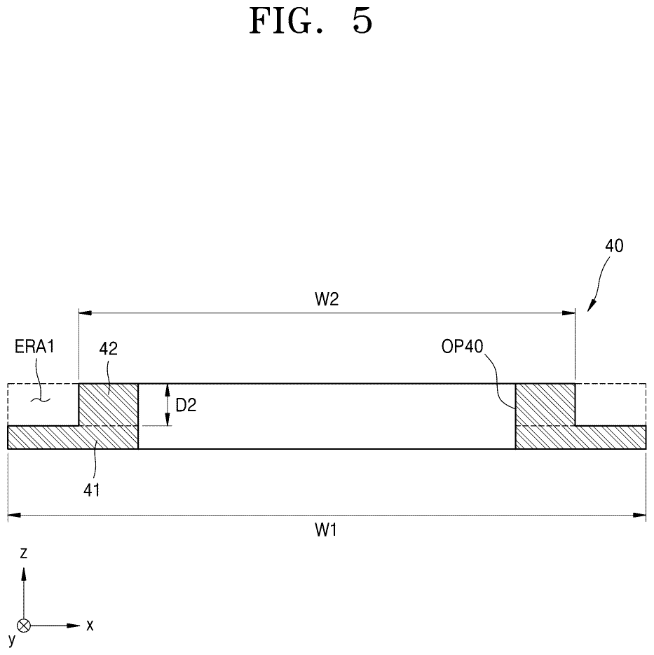

FIG. 4 is a schematic plan view of the mask assembly 40 according to an embodiment, and FIG. 5 is a schematic cross-sectional view of the mask assembly 40 according to an embodiment. Specifically, FIG. 5 is a cross-sectional view of the mask assembly 40, taken along line V-V′ of FIG. 4.

Referring to FIGS. 4 and 5, the mask assembly 40 may include a first mask portion 41 and a second mask portion 42.

The mask assembly 40 may be formed by connecting a plurality of side structures and may include a mask opening OP40 defined by the plurality of side structures. That is, the mask opening OP40 may be surrounded by the plurality of side structures and may pass through the center of the mask assembly 40. The mask opening OP40 may particularly pass through the first mask portion 41 and the second mask portion 42 in the first direction (e.g., the +z axis and/or −z axis direction).

In an embodiment, the mask assembly 40 may be a quadrangular frame. However, the shape of the mask assembly 40 is not limited thereto, and the mask assembly 40 may have various polygonal shapes. Hereinafter, for convenience of description, the following will primarily describe the case where the mask assembly 40 is a quadrangular frame.

In the case where the mask assembly 40 is a quadrangular frame, the plurality of side structures may include a first side structure extending in the second direction (e.g., the +x axis and/or −x axis direction) and a second side structure extending in the third direction (e.g., the +y axis and/or −y axis direction). The first side structure may include a pair of straight sections that are parallel to and face each other, and the second side structure may include a pair of straight sections that are parallel to and face each other. The first side structure may be connected to the second side structure. In an embodiment, the first side structure may extend along a short side of the mask assembly 40, and the second side may extend along a long side of the mask assembly 40. However, embodiments of this disclosure are not limited thereto, and the first side structure may extend along a long side of the mask assembly 40 and the second side structure may extend along a short side of the mask assembly 40, or the lengths of the first side structure and the second side structure may be the same. Hereinafter, for convenience of description, the following primarily describes the case where the first side structure is shorter than the second side structure.

The first mask portion 41 and the second mask portion 42 may be integrally formed. The second mask portion 42 may extend in the first direction (e.g., the +z axis direction) from the first mask portion 41 to the display substrate DS (see FIG. 1). That is, the second mask portion 42 may protrude from the first mask portion 41. A width W2 of the second mask portion 42 may be less than a width W1 of the first mask portion 41. In this structure, a portion of the first mask portion 41 may not overlap the second mask portion 42. A first space ERA1 may be on the first mask portion 41 that does not overlap the second mask portion 42. In this case, the thickness of the first space ERA1 may be equal to a thickness D2 of the second mask portion 42.

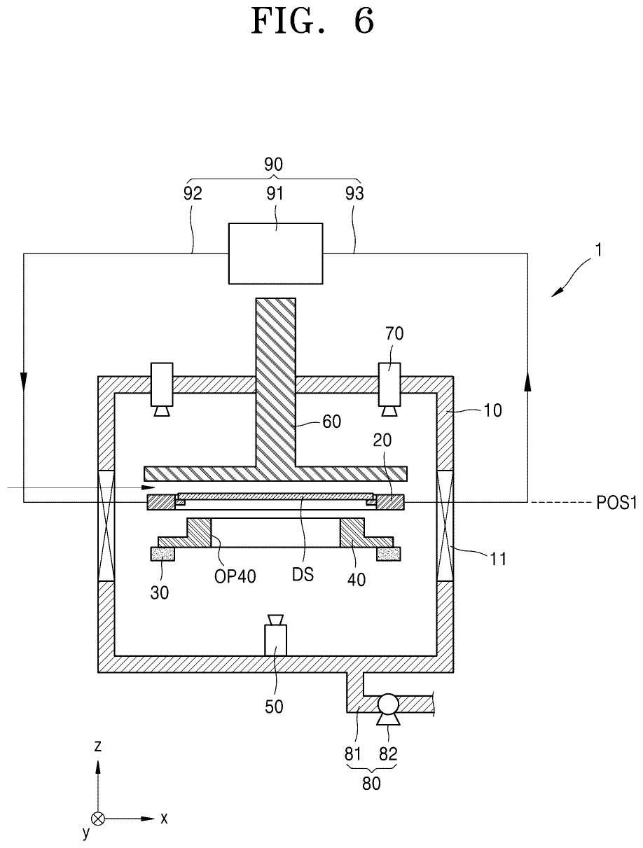

FIGS. 6 to 10 are schematic cross=sectional views of an apparatus 1 during manufacturing of a display apparatus according to an embodiment. Referring to FIGS. 6 to 10, a method using the apparatus 1 during manufacturing a display apparatus may be disclosed. In FIGS. 6 to 10, the same reference numerals as those of FIGS. 1 to 5 denote the same members, and redundant descriptions thereof may not be repeated below.

Referring to FIG. 6, the method of manufacturing a display apparatus may include the supply part 40 supplying a cooling material to the holder part 20, the cooling material flowing through the cooling passage 23 disposed inside the holder part 20, and the display substrate DS being brought into the chamber 10.

The flowing of the cooling material through the cooling passage 23 (see FIG. 2) may include flowing the cooling material through the third passage 233 (see FIG. 2) such that the cooling material is supplied from the supply part 90 to the first passage 231 (see FIG. 2), flowing the cooling material through the first passage 231 (see FIG. 2), flowing the cooling material through the second passage 232 (see FIG. 2), and flowing the cooling material through the fourth passage 234 (see FIG. 2) such that the cooling material returns from the fourth passage 234 (see FIG. 2) to the supply part 90.

The pressure adjustor 80 may maintain the interior of the chamber 10 at a desired pressure, e.g., a state equal or similar to atmospheric pressure. The gate valve 11 may operate to open the open portion of the chamber 10.

The display substrate DS may be loaded into the inside of the chamber 10 from the outside through the open portion of the chamber 10. The display substrate DS may be loaded into the chamber 10 in various ways. As an example, the display substrate DS may be loaded into the inside of the chamber 10 from the outside of the chamber 10 by a robot arm and the like arranged outside the chamber 10. In another embodiment, in the case where the holder part 20 has a shuttle form, the holder part 20 may be carried from the inside of the chamber 10 to the outside of the chamber 10, then, the display substrate DS may be seated on the holder part 20 by a separate robot arm arranged outside the chamber 10, and the holder part 20 may be carried (and thereby loaded) into the inside of the chamber 10 from the outside of the chamber 10.

The display substrate DS when inside of the chamber 10 may sit on the holder part 20. The display substrate DS may be disposed on the contact portion 22 (see FIG. 2) of the holder part 20. The contact portion 22 (see FIG. 2) may be in contact with the display substrate DS. The display substrate DS may overlap the holder opening OP21 (see FIG. 2). At least a portion of the display substrate DS may be received in the holder opening OP21 (sec FIG. 2).

The mask assembly 40 may be inside the chamber 10 as described above. In another embodiment, in an identical or similar manner to the loading of the display substrate DS, the mask assembly 40 may be loaded into the inside of the chamber 10 from the outside of the chamber 10.

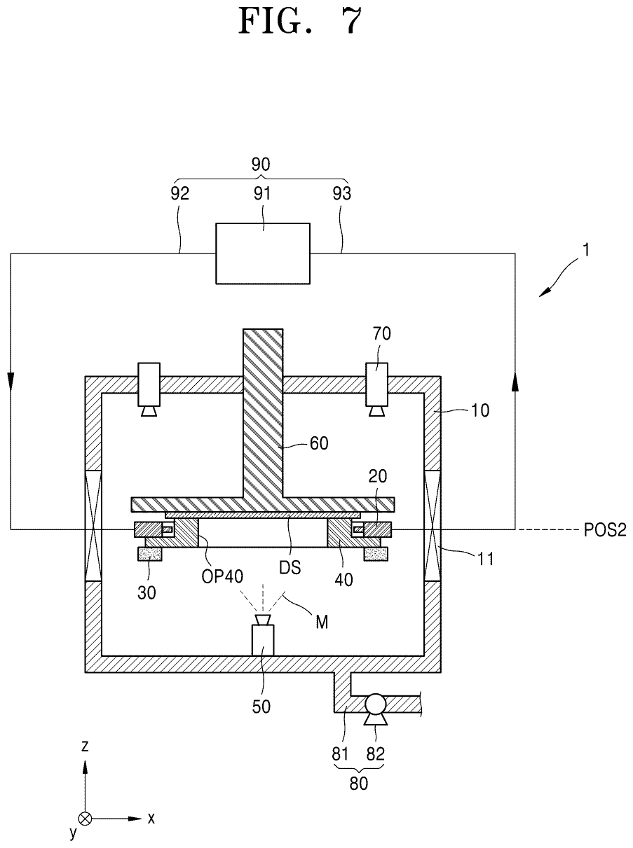

Referring to FIGS. 6 and 7, the method of manufacturing a display apparatus may include moving the holder part 20 between a first position POS1 and a second position POS2. As shown in FIG. 6, a position at which the holder part 20 supports the display substrate DS is denoted by the first position POS1, and as shown in FIG. 7, a position at which the holder part 20 is in contact with the mask assembly 40 is denoted by the second position POS2. That is, the holder part 20 may move between the first position POS1 and the second position POS2.

At the first position POS1, the holder part 20 may be apart from the mask assembly 40.

At the second position POS2, the holder part 20 may be in contact with the first mask portion 41. At the second position POS2, the holder part 20 may be apart from the first mask portion 41. At the second position POS2, at least a portion of the holder part 20 may be received in the first space ERA1. In this case, a thickness D2 (see FIG. 5) of the second mask portion 42 may be greater than a thickness D1 (see FIG. 3) of the holder part 20. That is, the thickness of the first space ERA1 may be greater than the thickness D1 of the holder part 20. Accordingly, at the second position POS2, the upper surface of the holder part 20 may not protrude from the upper surface of the mask assembly 40. In this structure, at the second position POS2, because the holder part 20 is apart from the display substrate DS, the display substrate DS may be in close proximity or contact with the mask assembly 40.

Referring to FIG. 7, when the holder part 20 moves to the second position POS2, the magnetic force part 60 may move toward the mask assembly 40r. Accordingly, the mask assembly 40 may be in contact with the display substrate DS, and the display substrate DS may be in contact with the magnetic force part 60.

In this case, the vision part 70 may be configured to capture images of or otherwise identify the positions of the display substrate DS and the mask assembly 40. The positions of the display substrate DS and the mask assembly 40 may be determined based on images captured by the vision part 70. In this case, the apparatus 1 for manufacturing a display apparatus may include a separate controller (not shown) to determine the positions of the display substrate DS and the mask assembly 40. When the positions of the display substrate DS and the mask assembly 40 have been determined, the supporter 30 may fine-adjust the position of the mask assembly 40 relative to the display substrate DS.

Referring to FIG. 7, the method of manufacturing a display apparatus may include the deposition source 50 supplying the deposition material M. The deposition source 50 operates to supply the deposition material M toward the mask assembly 40, and the deposition material M passing through the mask opening OP40 may pass through the mask assembly 40 and be deposited on the display substrate DS. In this case, the pump 82 may maintain the desired pressure in the chamber 10, e.g., at a state equal or similar to vacuum by sucking in the gas from inside the chamber 10 and discharging that gas to the outside.

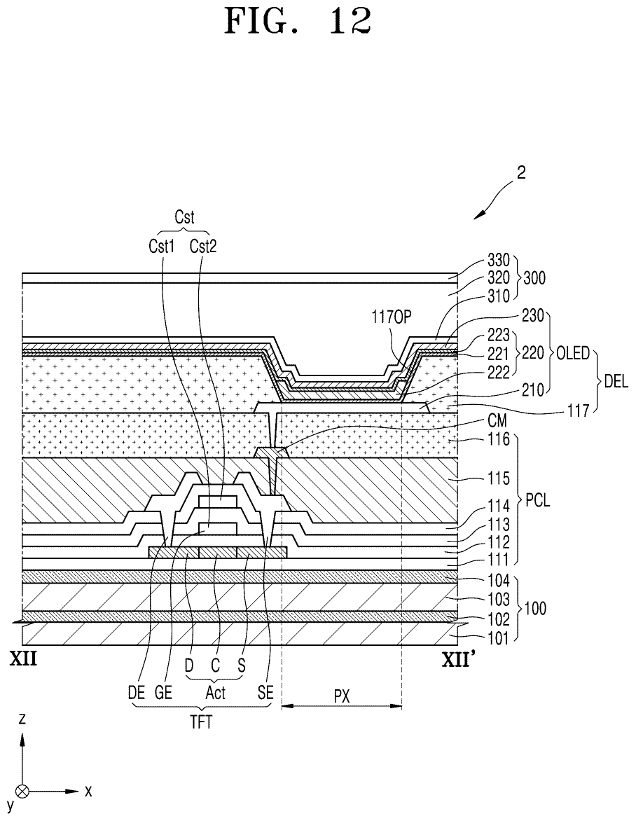

As described above, the deposition material M supplied from the deposition source 50 may pass through the mask assembly 40, be deposited on the display substrate DS, and thus, form at least one of a plurality of layers, for example, an organic layer, an inorganic layer, and a metal layer, which may be stacked in a display apparatus 2 (see FIG. 12) described below.

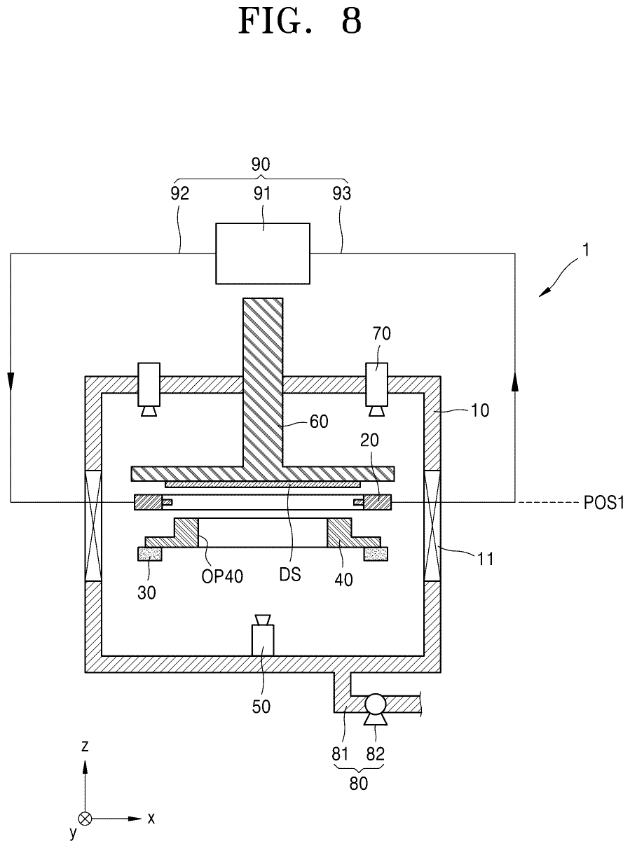

Referring to FIG. 8, the method of manufacturing a display apparatus may include carrying the display substrate DS on which the deposition is completed to the outside. The magnetic force part 60 may initially hold display substrate DS on which the deposition was completed. The display substrate DS may be carried out of the chamber 10 in various ways. As an example, the display substrate DS may be carried from the inside of the chamber 10 to the outside of the chamber 10 by a robot arm and the like arranged outside the chamber 10. During a process in which the display substrate DS is carried to the outside, the holder part 20 may be positioned at the first position POS1.

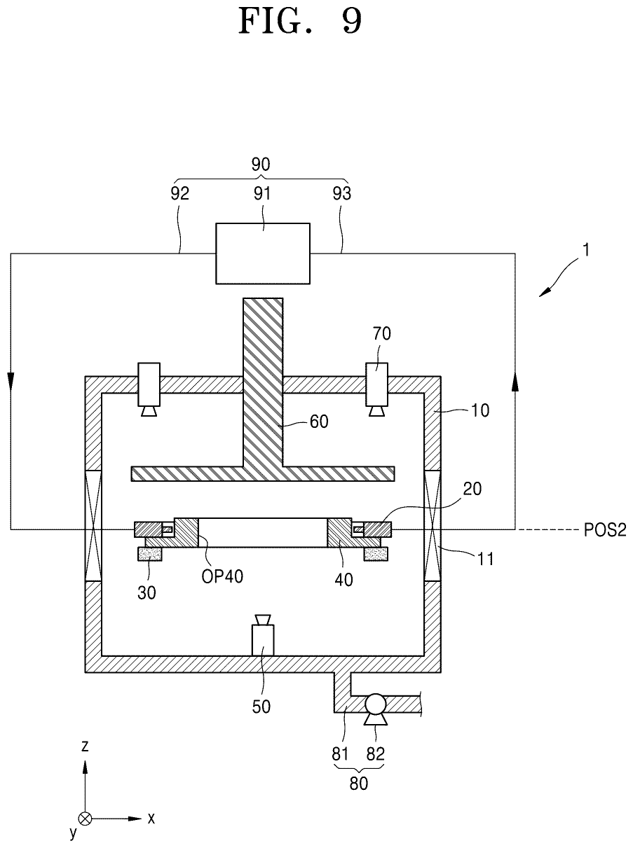

Referring to FIG. 9, the method of manufacturing a display apparatus may include allowing the holder part 20 to be in contact with the mask assembly 40 before the display substrate DS is carried into the chamber 10 or when the display substrate DS is otherwise not inside the chamber 10.

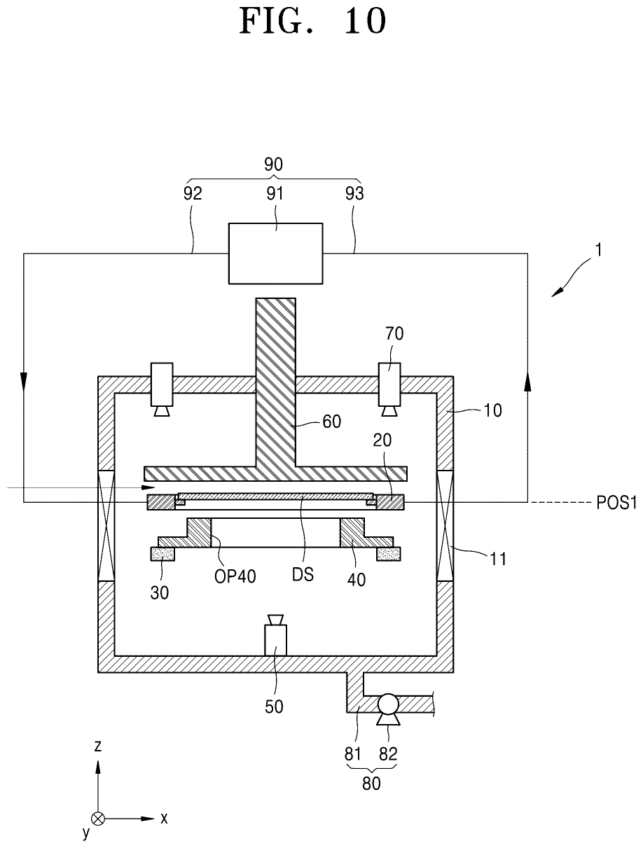

Referring to FIG. 10, the method of manufacturing a display apparatus may include carrying a new display substrate DS into the chamber 10. Because the above process is described with reference to FIG. 6, detailed description is omitted here.

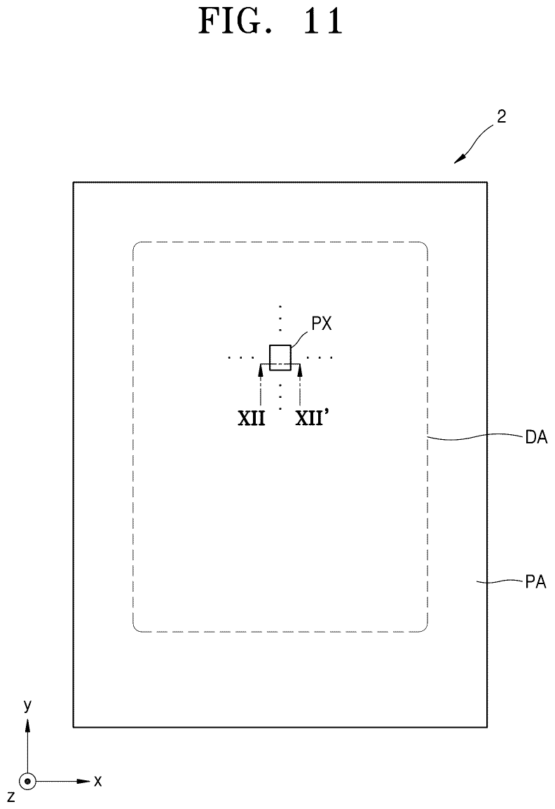

Referring to FIGS. 1 to 10, because the holder part 20 including the cooling passage 23 may be in contact with the mask assembly 40 at any time, the mask assembly 40 may be efficiently cooled. Accordingly, a phenomenon in which heat emitted from the deposition source 50 may transform or deform the mask assembly 40 may be reduced. Accordingly, durability and quality of the display apparatus 2 (see FIG. 11) manufactured using the apparatus 1 may be improved.

FIG. 11 is a schematic plan view of the display apparatus 2 according to an embodiment. Referring to FIG. 11, the display apparatus 2 manufactured according to an embodiment may include a display area DA and a peripheral area PA outside the display area DA. The display apparatus 2 may be configured to display images through an array of a plurality of pixels PX arranged two-dimensionally in the display area DA.

The peripheral area PA is a region that does not display images and may entirely or partially surround the display area DA. A driver and the like configured to provide electric signals or power to pixel circuits respectively corresponding to the pixels PX may be arranged in the peripheral area PA. A pad may be arranged in the peripheral area PA, wherein the pad is a region to which electronic elements or a printed circuit board may be electrically connected to the display apparatus 2.

The following primarily describes an embodiment of the display apparatus 2 that includes an organic light-emitting diode OLED as a light-emitting diode, but the display apparatus 2 according to embodiments of this disclosure are not limited thereto. In another embodiment, the display apparatus 2 may be a light-emitting display apparatus including an inorganic light-emitting diode, that is, an inorganic light-emitting display apparatus. The inorganic light-emitting diode may include a PN diode including inorganic semiconductor-based materials. When a forward voltage is applied to a PN-junction diode, holes and electrons are injected into an emission layer and energy created by recombination of the holes and the electrons is converted to light energy, and the light of a preset color characteristic of the emission layer may be emitted. The inorganic light-emitting diode may have a width in the range of several micrometers to hundreds of micrometers. In an embodiment, the inorganic light-emitting diode may be denoted by a micro light-emitting diode. In another embodiment, the display apparatus 2 may be a quantum-dot light-emitting display apparatus.

The display apparatus 2 may be used as a display screen in various products including televisions, notebook computers, monitors, advertisement boards, Internet of things (IoTs) apparatuses as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the display apparatus 2 according to an embodiment may be used in wearable devices including smartwatches, watchphones, glasses-type displays, and head-mounted displays (HMD). In addition, in an embodiment, the display apparatus 2 may be used as a display screen in instrument panels for automobiles, center fascias for automobiles, or center information displays (CIDs) arranged on a dashboard, rear view mirror displays that may replace side mirrors of automobiles, and displays of an entertainment system arranged on the backside of front seats for backseat passengers in automobiles.

FIG. 12 is a schematic cross-sectional view of the display apparatus 2 according to an embodiment, taken along line XII-XII′ of FIG. 12. Referring to FIG. 12, the display apparatus 2 may include a stack structure including the substrate 100, a pixel circuit layer PCL, a display element layer DEL, and an encapsulation layer 300. The display substrate DS (see FIG. 1) may be a structure in which at least one of, for example, the pixel circuit layer PCL, the display element layer DEL, and the encapsulation layer 300 is stacked on the substrate 100 during a process using the apparatus 1 when manufacturing the display apparatus 2.

The substrate 100 may have a multi-layered structure including a base layer that includes a polymer resin and an inorganic layer. As an example, the substrate 100 may include the base layer including a polymer resin and a barrier layer including an inorganic insulating layer. As an example, the substrate 100 may include a first base layer 101, a first barrier layer 102, a second base layer 103, and a second barrier layer 104 that are sequentially stacked. The first base layer 101 and the second base layer 103 may each include polyimide (PI), polyethersulfone (PES), polyacrylate, polyetherimide (PEI), polyethylene naphthalate (PEN), polyethylene terephthalate (PET), polyphenylene sulfide (PPS), polycarbonate (PC), cellulose tri acetate (TAC), and/or cellulose acetate propionate (CAP). The first barrier layer 102 and the second barrier layer 104 may each include an inorganic insulating material such as silicon oxide, silicon oxynitride, and/or silicon nitride. The substrate 100 may be flexible.

The pixel circuit layer PCL is disposed on the substrate 10. FIG. 12 shows an example in which the pixel circuit layer PCL includes a thin-film transistor TFT and a buffer layer 111, a first gate insulating layer 112, a second gate insulating layer 113, an interlayer insulating layer 114, and a first planarization insulating layer 115, and a second planarization insulating layer 116 under and/or on elements of the thin-film transistor TFT.

The buffer layer 111 may be configured to reduce or block foreign materials, moisture, or external air penetrating from below the substrate 100 and may provide a flat surface on the substrate 100. The buffer layer 111 may include an inorganic insulating material such as silicon nitride, silicon oxynitride, and silicon oxide, and include a single-layer structure or a multi-layered structure including the above materials.

The thin-film transistor TFT on the buffer layer 111 may include a semiconductor layer Act, and the semiconductor layer Act may include polycrystalline silicon. Alternatively, the semiconductor layer Act may include amorphous silicon, an oxide semiconductor, or an organic semiconductor. The semiconductor layer Act may include a channel region C, a drain region D, and a source region S with the drain region D and the source region S respectively arranged on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), and titanium (Ti) and have a single-layer structure or a multi-layered structure including the above materials.

The first gate insulating layer 112 between the semiconductor layer Act and the gate electrode GE may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

An upper electrode Cst2 of a storage capacitor Cst may be arranged on the second gate insulating layer 113. The upper electrode Cst2 may overlap the gate electrode GE therebelow. In this case, the gate electrode GE and the upper electrode Cst2 overlapping each other with the second gate insulating layer 113 therebetween may constitute the storage capacitor Cst. That is, the gate electrode GE may serve as a lower electrode Cst1 of the storage capacitor Cst.

In the illustrated embodiment, the storage capacitor Cst may overlap the thin-film transistor TFT. In an embodiment, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂). The interlayer insulating layer 114 may include a single layer or a multi-layer including the inorganic insulating material.

A drain electrode DE and a source electrode SE may each be disposed on the interlayer insulating layer 114. The drain electrode DE and the source electrode SE may be respectively connected to the drain region D and the source region S through contact holes through the insulating layers therebelow. The drain electrode DE and the source electrode SE may each include a material having high conductivity. The drain electrode DE and the source electrode SE may each include a conductive material including molybdenum (Mo), aluminum (Al), copper (Cu), and titanium (Ti) and include a single layer or a multi-layer including the above materials. In an embodiment, the drain electrode DE and the source electrode SE may each have a multi-layered structure of Ti/Al/Ti.

The first planarization insulating layer 115 may cover the drain electrode DE and the source electrode SE. The first planarization insulating layer 115 may include an organic insulating material, which may include a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The second planarization insulating layer 116 may be disposed on the first planarization insulating layer 115. The second planarization insulating layer 116 may include the same material as a material of the first planarization insulating layer 115 and may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be disposed on the pixel circuit layer PCL having the structure described above. The display element layer DEL may include an organic light-emitting diode OLED as a display element (that is, a light-emitting element). The organic light-emitting diode OLED may have a stack structure including a pixel electrode 210, an intermediate layer 220, and a common electrode 230. The organic light-emitting diode OLED may be configured to emit, for example, red, green, or blue light, or emit red, green, blue, or white light. The organic light-emitting diode OLED may be configured to emit light through an emission area. The emission area may define a pixel PX.

The pixel electrode 210 of the organic light-emitting diode OLED may be electrically connected to the thin-film transistor TFT. In particular, the pixel electrode may extend through contact holes formed in the second planarization insulating layer 116 and the first planarization insulating layer 115 to a contact metal CM that is disposed on the first planarization insulating layer 115 and electrically connected to the source electrode SE in the illustrated embodiment.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the pixel electrode 210 may further include a layer on/under the reflective layer, the layer including ITO, IZO, ZnO, or In₂O₃.

A pixel-defining layer 117 may be disposed on the pixel electrode 210 and may include an opening 117OP exposing the central portion of the pixel electrode 210. The pixel-defining layer 117 may include an organic insulating material and/or an inorganic insulating material. The opening 117OP may define the emission area of light emitted from the organic light-emitting diode OLED. As an example, the size/width of the opening 117OP may correspond to the size/width of the emission area. Accordingly, the size and/or width of the pixel PX may depend on the size and/or width of the opening 117OP of the pixel-defining layer 117.

The intermediate layer 220 may include an emission layer 222 formed to correspond to the pixel electrode 210. The emission layer 222 may include a polymer organic material or a low-molecular weight organic material emitting light having a preset color. Alternatively, the emission layer 222 may include an inorganic emission material or quantum dots.

In an embodiment, the intermediate layer 220 may include a first functional layer 221 and a second functional layer 223 respectively disposed under and on the emission layer 222. The first functional layer 221 may include, for example, a hole transport layer (HTL), or include an HTL and a hole injection layer (HIL). The second functional layer 223 is an element disposed on the emission layer 222 and may include an electron transport layer (ETL) and/or an electron injection layer (EIL). Like the common electrode 230 described below, the first functional layer 221 and/or the second functional layer 223 may be common layers covering the substrate 100 entirely.

The common electrode 230 may be disposed on the pixel electrode 210 and may overlap the pixel electrode 210. The common electrode 230 may include a conductive material having a low work function. As an example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the common electrode 230 may further include a layer on the (semi) transparent layer, the layer including ITO, IZO, ZnO, or In₂O₃. The common electrode 230 may be integrally formed to cover the substrate 100 entirely.

The encapsulation layer 300 may be disposed on the display element layer DEL and may cover the display element layer DEL. The encapsulation layer 300 may include at least one inorganic encapsulation layer and at least one organic encapsulation layer. FIG. 12 shows an embodiment in which the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, and polyethylene. In an embodiment, the organic encapsulation layer 320 may include acrylate. The organic encapsulation layer 320 may be formed by hardening a monomer or coating a polymer. The organic encapsulation layer 320 may be transparent.

Although not shown, a touch sensor layer may be disposed on the encapsulation layer 300. An optical functional layer may be disposed on the touch sensor layer. The touch sensor layer may obtain coordinate information corresponding to an external input, for example, a touch event. The optical functional layer may be configured to reduce the reflectivity of light (external light) incident toward the display apparatus from outside, and/or improve the color purity of light emitted from the display apparatus. In an embodiment, the optical functional layer may include a phase retarder and/or a polarizer. The phase retarder may include a film-type phase retarder or a liquid crystal-type phase retarder. The phase retarder may include a λ/2 phase retarder and/or a λ/4 phase retarder. The polarizer may include a film-type polarizer or a liquid crystal-type polarizer. The film-type polarizer may include a stretchable synthetic resin film, and the liquid crystal-type polarizer may include liquid crystals arranged in a predetermined arrangement. Each of the phase retarder and the polarizer may further include a protective film.

An adhesive member may be disposed between the touch sensor layer and the optical functional layer. For the adhesive member, a general adhesive member known in the art may be employed without limitation. The adhesive member may be a pressure sensitive adhesive (PSA).

According to embodiments, the durability of the display apparatus may improve, and the quality of the display apparatus may improve.

Effects provided in embodiments in accordance with this disclosure are not limited to the above mentioned effects and other effects not mentioned may be clearly understood by those of ordinary skill in the art from the following claims.

Embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display apparatus, the apparatus comprising:
a chamber;
a mask assembly disposed inside the chamber to face a display substrate;
a holder part disposed inside the chamber, the holder part including a cooling passage through which a cooling material flows; and
a deposition source disposed inside the chamber and configured to supply a deposition material such that the deposition material passes through the mask assembly and is deposited on the display substrate,
wherein at least one of the holder part and the mask assembly is movable between a first position at which the holder part supports the display substrate and a second position at which the holder part is in contact with the mask assembly.

2. The apparatus of claim 1, wherein the holder part includes:
a holder frame around a holder opening; and
a contact portion extending from the holder frame toward the holder opening, the contact portion being positioned to contact the display substrate at the first position.

3. The apparatus of claim 2, wherein the cooling passage includes a first passage disposed inside the holder frame to surround the holder opening.

4. The apparatus of claim 3, wherein the cooling passage further includes a second passage extending from the first passage and having at least a portion disposed inside the contact portion.

5. The apparatus of claim 3, further comprising a supply part configured to supply the cooling material to the holder part,
wherein the cooling passage further includes a third passage disposed inside the holder frame to supply the cooling material from the supply part to the first passage.

6. The apparatus of claim 5, wherein the cooling passage further includes a fourth passage disposed inside the holder frame such that the cooling material returns from the first passage to the supply part.

7. The apparatus of claim 1, wherein the mask assembly includes:
a first mask portion;
a second mask portion extending in a first direction from the first mask portion toward the display substrate; and
a mask opening passing through the first mask portion and the second mask portion in the first direction,
wherein a width of the second mask portion is less than a width of the first mask portion.

8. The apparatus of claim 7, wherein the holder part is in contact with the first mask portion at the second position.

9. The apparatus of claim 7, wherein the holder part is apart from the first mask portion at the second position.

10. The apparatus of claim 7, wherein a thickness of the second mask portion is greater than a thickness of the holder part.

11. A method of manufacturing a display apparatus, the method comprising:
flowing a cooling material through a cooling passage disposed inside a holder part;
bringing a display substrate into a chamber;
moving the holder part between a first position at which the holder part supports the display substrate and a second position at which the holder part contacts a mask assembly; and
supplying, by a deposition source, a deposition material.

12. The method of claim 11, wherein the holder part includes:
a holder frame around a holder opening; and
a contact portion extending from the holder frame toward the holder opening to be in contact with the display substrate.

13. The method of claim 12, wherein the flowing of the cooling material through the cooling passage includes flowing the cooling material through a first passage disposed inside the holder frame such that the cooling material surrounds the holder opening.

14. The method of claim 13, wherein the flowing of the cooling material through the cooling passage further includes flowing the cooling material through a second passage extending from the first passage and having at least a portion disposed inside the contact portion.

15. The method of claim 13, further comprising supplying, by a supply part, the cooling material to the holder part,
wherein the flowing of the cooling material through the cooling passage further includes flowing the cooling material through a third passage disposed inside the holder frame such that the cooling material is supplied from the supply part to the first passage.

16. The method of claim 15, wherein the flowing of the cooling material through the cooling passage further includes flowing the cooling material through a fourth passage disposed inside the holder frame such that the cooling material returns from the first passage to the supply part.

17. The method of claim 11, wherein the mask assembly includes:
a first mask portion;
a second mask portion extending in a first direction from the first mask portion to the display substrate; and
a mask opening passing through the first mask portion and the second mask portion in the first direction,
wherein a width of the second mask portion is less than a width of the first mask portion.

18. The method of claim 17, wherein the holder part is in contact with the first mask portion at the second position.

19. The method of claim 17, wherein the holder part is apart from the first mask portion at the second position.

20. The method of claim 17, wherein a thickness of the second mask portion is greater than a thickness of the holder part.
